(19) United States
(12) Patent Application Publication
(10) Pub. No.: US 2021/0041589 A1
(43) Pub. Date: Feb. 11, 2021

(54) Method For Computing Time Shifts Between Seismic Signals

(71) Applicant: ExxonMobil Upstream Reseaech Company, Spring, TX (US)

(72) Inventors: Hong Zhao, Houston, TX (US); Valeriy Brytik, Houston, TX (US); Anatoly I. Baumstein, Houston, TX (US); Yaxun Tang, Spring, TX (US); Sirui Tan, Spring, TX (US)

(21) Appl. No.: 15/929,499

(22) Filed: May 6, 2020

Related U.S. Application Data
(60) Provisional application No. 62/884,858, filed on Aug. 9, 2019.

(51) Int. Cl. G01V 1/36; G01V 1/30; G01V 1/28; G06F 30/20

(52) U.S. Cl. CPC G01V 1/36; G01V 1/305; G01V 2210/612; G06F 30/20; G01V 2210/20; G01V 1/282

(57) ABSTRACT

Seismic data processing may include computing the travel time shift between two seismic signals or the depth shift between two seismic images. In Full Waveform Inversion (FWI), the travel time difference between an observed trace and a simulated trace may be computed such that the two traces match after the travel time shift is applied to the observed trace. The travel time shift may be computed based on a constrained optimization that maximizes the windowed cross-correlation between the two seismic traces by constraining the time derivative of the travel time shift to be less than a constant while maximizing the windowed cross-correlation. Further, the travel time shift may be computed during the model line search in FWI by computing a plurality of travel time shifts where a first travel time shift is dependent on the observed trace and a second travel time shift is independent of the observed trace.

### CROSS REFERENCE TO RELATED APPLICATION

This application claims the priority benefit of U.S. Provisional Application No. 62/884,858 titled “Method for Computing Time Shifts Between Seismic Signals”, filed on Aug. 9, 2019, the disclosure of which is incorporated herein by reference in its entirety.

### TECHNICAL FIELD

The disclosure generally relates to the field of geophysical prospecting for hydrocarbons and more particularly to seismic data processing. Specifically, the disclosure relates to computing time shifts between seismic signals.

### BACKGROUND

Full wavefield inversion (FWI) is a nonlinear inversion technique that recovers the subsurface earth model by minimizing the mismatch between the simulated and the observed seismic waveforms or other type of measured geophysical data. Due to the high computational cost associated with FWI, conventional implementations utilize local optimization techniques to estimate optimal model parameters. One local optimization technique is the gradient-based first-order method (e.g., steepest descent or nonlinear conjugate gradient), which utilizes only the gradient information of the objective function to define a search direction. In particular, the search direction unit vector s is related to the model update process by m_{updated}=m+αs, where α (a scalar) is the step size.

In FWI and time-lapsed seismic signal process, one may seek to compute the travel time shift (also known as the travel time difference) between two seismic signals or the depth shift between two seismic images. In particular, one may compute the travel time difference τ(t) between an observed trace u_{obs}(t) and a simulated trace uₛᵢₘ(t). The observed trace u_{obs}(t) is based on the observed seismic data, which may be generated by one or more sensors and which has been preprocessed before FWI. The simulated trace uₛᵢₘ(t) is generated using a computer simulation program based on a combination of subsurface property models. FWI seeks to improve the existent subsurface property models by minimizing the travel time difference between u_{obs} and uₛᵢₘ. The improved subsurface property models may ultimately be used for any one, any combination or all of: improving estimation of reservoirs and making decisions regarding the development of the field; predicting future production; placing additional wells; or evaluating alternative reservoir management scenarios.

After the travel time shift is applied to u_{obs}(t), the two traces may match (or substantially match) as shown in the following:

u_{obs}(t+τ(t))≈uₛᵢₘ(t) (1)

where the time shift τ(t) may be time dependent by itself. In FWI, the estimated τ(t) may be used to update the background velocity model by using the adjoint state method, so that τ(t) is driven closer to zero during every FWI iteration. Ideally, after a sufficient number of iterations, the resulting subsurface property models produce simulated data that kinematically matches the observed data. Other applications for determining time shifts include matching migrated seismic images in depth domain for time-lapse seismic data processing.

Similar to estimating the shift in time-lapsed seismic images, the travel time shift may be estimated by first computing the windowed cross-correlation between u_{obs}(t) and uₛᵢₘ(t), which is defined as follows:

$$C ( t ; ξ ) = \frac{\int w ( t - s ) {u}_{s i m} ( s ) {u}_{o b s} ( s + ξ ) ds}{\sqrt{\int w ( t - s ) {u}_{sim}^{2} ( s ) d s} \sqrt{\int w ( t - s ) {u}_{obs}^{2} ( s + ξ ) ds}} , \qquad ( 2 )$$

where τ is time shift, and where w is a windowing function (e.g., a Gaussian function). At every time t, the optimal travel time shift τ(t) may be estimated by finding the maximum of the correlation coefficients, as shown in the following:

$$τ ( t ) = {arg max}_{ξ} C ( t ; ξ ) , \qquad ( 3 )$$

Algorithms based on equations (2) and (3) have been applied to obtain high-resolution shift in time-lapsed seismic images, where the two images typically have very similar waveforms and the travel time shift itself is of small magnitude.

Another option for chemometric data analysis is using a so-called correlation optimized warping. In this methodology, both signals are divided into segments, and the segments of one trace are linearly stretched or compressed to achieve maximal correlation with the other reference trace.

Still another option is dynamic time warping to address the lack of smoothness of τ(t), thereby solving the global optimization problem according to the following:

$$τ ( t ) = {arg min}_{ξ ( t )} \int {\vert {u}_{s i m} ( t ) - {u}_{o b s} ( t + ξ ( t ) ) \vert}^{2} dt , \qquad ( 4 )$$

where τ(t) must satisfy:

τ(t+Δt)−τ(t)=0 or ±Δt (5)

In this regard, determining the travel time shift τ(t) may be difficult, particularly for FWI.

### SUMMARY

In one implementation, a method of estimating travel time difference between two seismic traces is disclosed. The method includes: accessing seismic data, the seismic data being generated from one or more sensors; determining, based on the seismic data, an observed trace; computing, using at least one computer and based on a model of the seismic data, a simulated trace; computing, using the at least one computer, a windowed cross correlation between the observed trace and the simulated trace; determining travel time difference between the observed trace and the simulated trace by maximizing the windowed cross correlation at least partly while constraining at least one aspect of the travel time difference between the observed trace and the simulated trace; and using the determined travel time difference between the observed trace and the simulated trace in order to update the model of the seismic data.

In another implementation, an iterative method for inverting measured geophysical data to infer a subsurface model of one or more physical properties is disclosed. The method includes: (a) using a subsurface property model, computing, using at least one computer, an objective function measuring misfit between model-simulated data and the measured geophysical data, wherein the model-simulated data are generated using a computer; (b) computing, using the at least one computer, a search direction of the objective function with respect to parameters of the subsurface property model; (c) computing, using at least one computer, a travel time shift between simulated data from the subsurface property model perturbed and observed data by computing a plurality of travel time shifts, at least one of the plurality of travel time shifts computed being independent of the observed data, the observed data based on the geophysical data; (d) using the computed travel time shift for performing a line search; (e) updating the subsurface property model using the line search; and (f) repeating (a)-(e) at least once using the updated subsurface property model.

### DESCRIPTION OF THE FIGURES

The present application is further described in the detailed description which follows, in reference to the noted plurality of drawings by way of non-limiting examples of exemplary implementations, in which like reference numerals represent similar parts throughout the several views of the drawings.

FIG. 1 is a flow diagram for computing travel time shift based on constrained optimization that maximizes the windowed cross correlation between two seismic traces.

FIG. 2 is a flow diagram for computing travel time shift during the model line search for FWI.

FIG. 3 is an example graph of seismic input traces including observed seismic data and simulated seismic data.

FIG. 4 is a contour plot of the shifted windowed cross-correlation between simulated and observed traces, where the horizontal axis is time and the vertical axis is time shift with the solid line indicating the travel time shift computed by taking the maximum of the cross-correlation function at every time slice and the dashed line indicating the input time shift.

FIG. 5 is a contour plot of the square difference between the simulated trace and the observed trace with the time shift computed according to dynamic time warping. The horizontal axis is time and the vertical axis is time shift with the solid line indicating the travel time shift extracted based on equations (4) and (5), and the dashed line indicating the input time shift.

FIG. 6 is a contour plot based on the shifted windowed cross-correlation (e.g., windowed cross-correlation is multiplied by −1) between simulated and observed traces, where the horizontal axis is time and the vertical axis is time shift, with the solid line indicating the travel time shift computed based on the constrained optimization algorithm, and the dashed line indicating the input time shift.

FIG. 7 is an example graph of seismic output traces with one line indicating observed data after being stretched by the time shift computed in FIG. 6, and another line indicating simulated data.

FIG. 8 is a diagram of an exemplary computer system that may be utilized to implement the methods described herein.

### DETAILED DESCRIPTION

The methods, devices, systems, and other features discussed below may be embodied in a number of different forms. Not all of the depicted components may be required, however, and some implementations may include additional, different, or fewer components from those expressly described in this disclosure. Variations in the arrangement and type of the components may be made without departing from the spirit or scope of the claims as set forth herein. Further, variations in the processes described, including the addition, deletion, or rearranging and order of logical operations, may be made without departing from the spirit or scope of the claims as set forth herein.

As discussed in the background, one option for determining the travel time shift is according to equations (2) and (3). However, when applied to the more complicated FWI problem, the solution using equations (2) and (3) is less effective. In FWI, uₛᵢₘ and n_{obs} may have different frequency contents and thus locally dissimilar waveforms; n_{obs} can often contain events that are missing in uₛᵢₘ and vice versa. The time shift may be comparable to the characteristic time period of the signal itself, forcing one to search for the optimal time shift in a wide time window range. Any peak in uₛᵢₘ may be matched to several neighboring peaks of u_{obs}, all with locally maximal correlations.

One reason for the aforementioned difficulties is that equations (2) and (3) compute the travel time shift τ(t) independently for every time t using equation (3). Indeed, the local optimal condition in equation (3) does not impose any smoothness constraint for travel time shift τ(t). Thus, the computed travel time shift τ(t) may exhibit spurious jumps between neighboring time samples, which corresponds to matching unrelated events between the two traces. One remedy is to heavily smooth the estimated travel time shift, which may reduce the resolution and reliability of the travel time shift estimation. Another option is to replace the original signals in equation (2) with their Hilbert envelopes; however, the search for maximum local correlation still follows the local optimal condition in equation (3), and thus the computed travel time shift may still suffer from spurious discontinuities in time.

Further, with regard to the so called correlation optimized warping, when applied in FWI, difficulties may occur when uₛᵢₘ and u_{obs} have different frequency contents and thus different characteristic widths of peaks and troughs. In this case, the algorithm may stretch or compress seismic traces to match local waveforms instead of travel times.

In addition, with dynamic time warping, because of the constraint in equation (5), the travel time shift τ(t) computed in this manner is continuous in time, but not necessarily reliable for FWI. Since equation (4) strives to minimize the absolute difference between the two signals, it may result in overfitting, whereby the solution for the travel time shift τ(t) is driven by waveform difference instead of travel time difference, similar to the case with the correlation optimized warping method. In the presence of noise, the square of difference between uₛᵢₘ(t) and shifted u_{obs}(t) has a rough shape. This may result in a continuous but rugged τ(t) estimation.

Finally, the line search step in an FWI workflow poses another challenge to the travel time shift estimation. For every FWI iteration, one perturbs the current earth model along a search direction and by a different distance α^{(j)} (j=1, 2, . . . , J), and chooses the model perturbation that minimizes the travel time shift. It is thus desired that the travel time shift between uₛᵢₘ and u_{obs} varies continuously and monotonically with search step length α. However, such a requirement may be difficult to satisfy if one directly computes the shift between u_{obs} and uₛᵢₘ for every model perturbation. This is due to the computation of the travel time shift τ(t) being highly nonlinear when u_{obs} and uₛᵢₘ have dissimilar waveforms, which is often the case in FWI.

Thus, in one implementation, the travel time shift τ(t) is computed by maximizing the windowed cross correlation while constraining at least one aspect of the travel time shift τ(t) (e.g., constraining dτ(t)/dt, as discussed further below). In such an implementation, a constrained global optimization approach is used; however, instead of minimizing the square of waveform difference, the windowed cross-correlation is maximized between the two seismic traces. By doing so, the extracted travel time shift may have lower temporal resolution, but may have better smoothness and may be less affected by noise and local waveform difference. Thus, this approach may be more suited to application in the context of FWI.

In a specific implementation, τ(t) is found by solving the following constrained optimization problem:

$$τ ( t ) = {arg min}_{ξ ( t )} \int - C ( t ; ξ ( t ) ) dt , \qquad ( 6 )$$

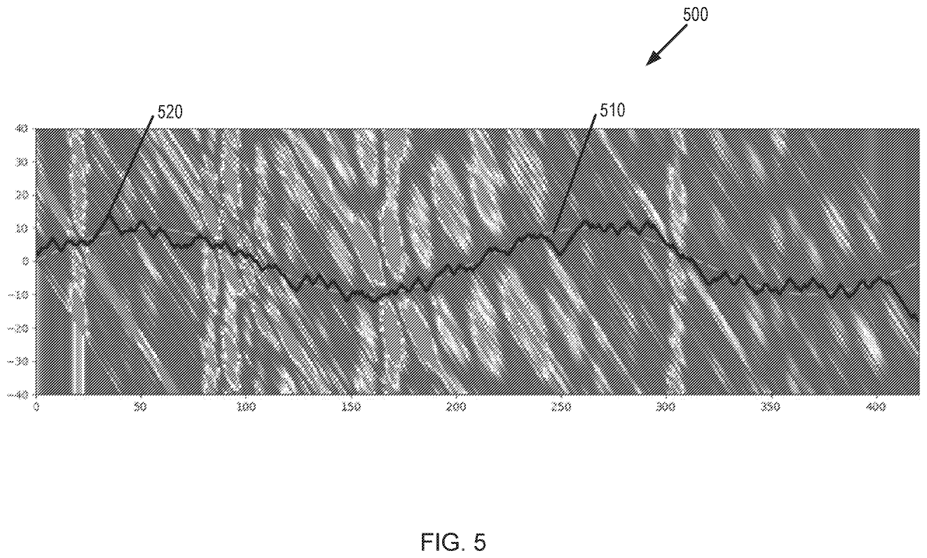

under the at least one constraint of τ(t). Various constraints of τ(t) are contemplated including the following:

|dτ(t)/dt|≤MAX_SLOPE (7)

where the absolute value of dτ(t)/dt is constrained to be less than or equal to MAX_SLOPE. In this way the absolute value of dτ(t)/dt is constrained to be less than a derivative value. In one implementation, MAX_SLOPE is a constant that is between 0 and 1 and controls how fast τ(t) may vary in time. Further, equation (6) may be integrated over one or more periods of time. As one example discussed further below with regard to FIG. 5, integration may be for a time window over the entire time period (e.g., 0 to 425) or may be piecewise integrated for one, some, or all of the different time windows of a subpart (e.g., 0 to 100; 100 to 200; etc.). In particular, the time window for integration may be selected in order to match multiple shot gathers. This is in contrast to a point-by-point analysis, such as used in equation (3).

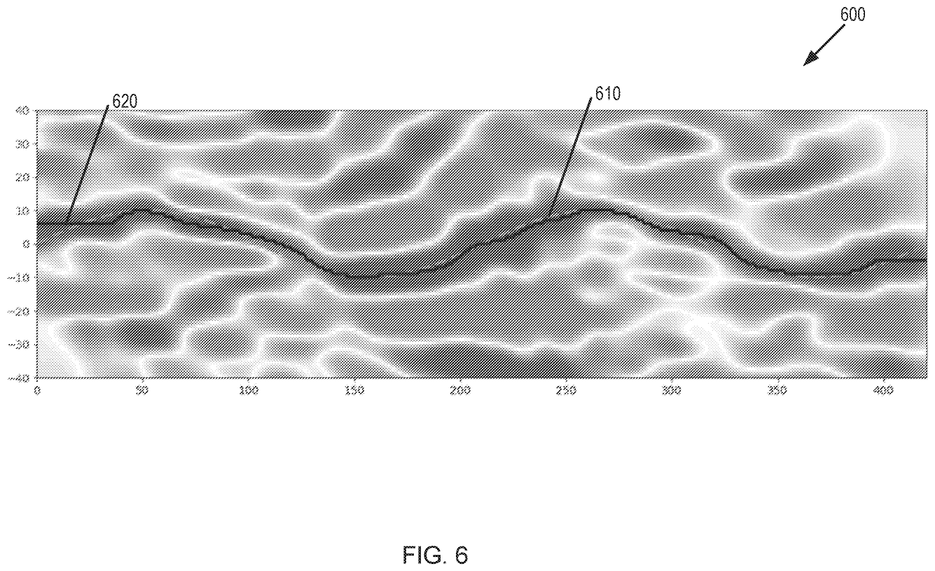

The globally optimal solution to equations (6) and (7) may be efficiently computed by using a dynamic programming algorithm. Further, the sign of the slope of τ(t) computed based on equations (6) and (7) is consistent with the prescribed time shift (e.g., 610, dashed vs solid curves in FIG. 6). This is in contrast to dynamic time warping, where the output time shift can exhibit unphysical and excessive oscillations (see e.g. 510 in FIG. 5). Thus, the slope of the output (see e.g. 610) may oscillate less, may be more consistent with, and may be closer to the true time shift than the output generated by conventional dynamic time warping.

In one implementation, the selection of the value for MAX_SLOPE may be a pre-determined constant and non-changing. In an alternate implementation, the selection of the constant for MAX_SLOPE may be dynamic. As one example, the dynamic selection may be based on an analysis of one or both of u_{obs} and uₛᵢₘ.

Thus, in practice, the value for MAX_SLOPE may be a tunable parameter. For example, the value for MAX_SLOPE may be based on an estimation of the error. In particular, the value for MAX_SLOPE may be based on the estimation of the maximum relative error in the current subsurface velocity models (e.g., MAX_SLOPE selected as proportional to the maximum relative subsurface velocity error). The estimated error may then be used to select the value for MAX_SLOPE.

As one example, the estimated error may be represented as a percentage, such as 10% error, 20% error, or the like. Other representations of the error are contemplated. The correlation between the estimated error and the value for MAX_SLOPE may use a simple argument, thereby translating the estimated error in the model to the value for MAX_SLOPE. In one implementation, the estimated error and the value for MAX_SLOPE may be directly correlated. In particular, the value for MAX_SLOPE may be selected to be no greater than, such as less than, the percent error (e.g., a 20% error translates into MAX_SLOPE≤0.2; a 30% error translates into MAX_SLOPE≤0.3; etc.).

Further, the constraint of τ(t) may vary for different iterations. For example, the value for MAX_SLOPE may vary based on the current iteration of the model (e.g., analyze the estimated error for one, some, or each iteration and select the MAX_SLOPE accordingly based on the estimated error). As another example, inversion may be implemented in multiple stages, with a first stage including one or multiple iterations and a second stage, which is subsequent to the first stage, including one or multiple iterations. Prior to the first stage, one or more parameters, including the value for MAX_SLOPE, may be selected. After completion of the first stage, the methodology may pause temporarily in order to perform an analysis of the current iteration of the model in order to determine whether to adjust any one of the parameters, such as the value for MAX_SLOPE. Further, the value for MAX_SLOPE selected for the first stage may be more aggressive (e.g., closer to the value=1). After a few iterations, the model is likely closer to the true model. In that regard, the value for MAX_SLOPE may be selected less aggressively (e.g., closer to the value=0). Thus, the value for MAX_SLOPE may be decreased as the methodology progressively iterates.

As discussed above, the travel time shift may be used for various aspects in FWI. For example, the travel time shift may be computed during the model line search in FWI. In particular, for FWI line search, the unperturbed earth model m⁽⁰⁾ (e.g., the current model) and a series of perturbed models may be considered. The series of perturbed models may be represented by the following: m^{(j)}=m⁽⁰⁾+α^{(j)}·s (j=1, 2, . . . , J), where s is a normalized model search direction and α^{(j)} is search step length. Each perturbed model m^{(j)} may be used for simulated data u^{(j)}. However, computing the travel time shift for the perturbed models may be difficult when the underlying seismic traces vary considerably or are prone to noise.

In one implementation, instead of directly computing the travel time shift between u^{(j)} and observed data u_{obs} (e.g., a difference between u^{(j)} and u_{obs}), the following approximation is used:

shift(u^{(j)}→u_{obs})≈shift(u_{ref}→u_{obs})−shift(u_{ref}→u^{(j)}), (8)

where u_{ref} is a reference trace, which is chosen to be u⁽⁰⁾. In particular, u_{ref} is the data simulated based on the unperturbed earth model m⁽⁰⁾ during FWI line search. In effect, the time shift between perturbed simulated data u^{(j)} and the observed data u_{obs} is cast as the difference between (1) the unperturbed time shift (e.g., the time shift between unperturbed simulated data u⁽⁰⁾ and the observed data u_{obs}) and (2) the time shift between unperturbed simulated data u⁽⁰⁾ and perturbed simulated data u^{(j)}.

Thus, the travel time shift between u^{(j)} and observed data u_{obs} may be determined by computing a plurality of travel time shifts, wherein at least one of the plurality of travel time shifts is independent of the observed data (e.g., shift(u_{ref}→u₍ⱼ₎) is independent of u_{obs}) and/or at least another of the plurality of travel time shifts is independent of the simulated data from the subsurface property model perturbed (e.g., shift(u_{ref}→u_{obs}) is independent of u^{(j)}.

Thus, the first term on the right-hand side of equation (8) is independent of u^{(j)}, and only the second term on the right-hand side of equation (8) depends on u^{(j)}. Because u_{ref} and u^{(j)} are simulated from models that differ by a small amount, they share similar waveforms except for the small time shift introduced by model perturbation α^{(j)}·s. Therefore, shift(u_{ref}→u^{(j)}) is approximately a linear function of α^{(j)}, and so is the estimated shift(u^{(j)}→u_{obs}), which is used to determine the optimal step length α^{(j)}. Using equation (8), the smoothness and convexity of the FWI objective function is effectively improved during the FWI line search, thus making the methodology more robust. In particular, because the second term measures the travel time shift between u_{ref} and u^{(j)}, it may vary smoothly with α^{(j)} because: u_{ref} and u^{(j)} are both simulated and therefore free of noise; and (2) u_{ref} and u^{(j)} have similar waveforms as they are synthesized using earth models that have minimal difference.

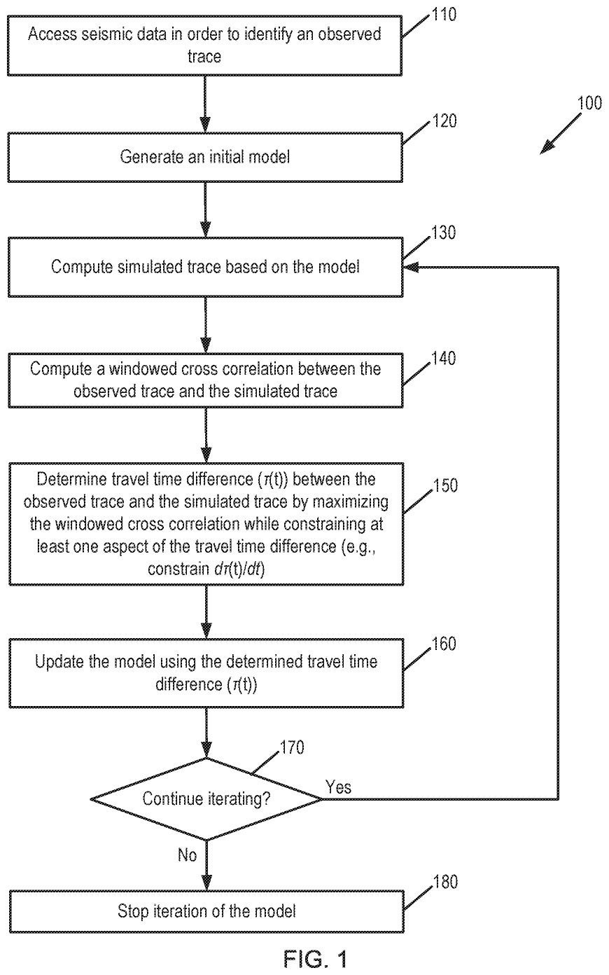

Referring to the figures, FIG. 1 is a flow diagram 100 for computing travel time shift based on constrained optimization that minimizes the windowed cross correlation between two seismic traces. At 110, seismic data is accessed in order to identify an observed trace (e.g., u_{obs}(t)). At 120, an initial model is generated. For example, with inversion-based seismic imaging algorithms, also known as waveform inversion, the subsurface model is iteratively updated to reduce data misfit defined by a certain objective function. In this regard, an initial subsurface model may be generated and iteratively updated.

At 130, the simulated trace is computed from the subsurface model. At 140, a windowed cross correlation is computed between the observed trace and the simulated trace. As one example, equation (2) illustrates one way in which to compute the windowed cross correlation between the observed trace u_{obs}(t) and the simulated trace u_{obs}(t). At 150, the travel time difference (τ(t)) between the observed trace and the simulated trace is determined by maximizing the windowed cross correlation while constraining at least one aspect of the travel time difference. As one example, the absolute value of the derivative of the travel time difference (dτ(t)/dt) is constrained to be less than or equal to a MAX_SLOPE. As discussed above, in one implementation the value for MAX_SLOPE is between 0 and 1.

At 160, the model is updated using the determined travel time difference (τ(t)). As one example, the determined travel time difference τ(t) may be used to update the background velocity model by using the adjoint state method, so that τ(t) is driven closer to zero during every FWI iteration. At 170, it is determined whether to continue iteration. As one example, iteration continues if the updated model has not sufficiently converged (e.g., the simulated seismic data generated from the updated model is significantly different from the actual seismic data). If so, flow diagram 100 loops back to 130. If not, at 180, iteration of the model is stopped.

As discussed above, for each of the iterations, block 150 may use the same parameters to constrain the aspect of the travel time difference. For example, the value for MAX_SLOPE may be constant for the different iterations when flow diagram 100 loops back to 130. Alternatively, the value for MAX_SLOPE may vary for the different iterations when flow diagram 100 loops back to 130. In particular, selection of the value for MAX_SLOPE may be based on analysis of error of at least one aspect of the model (e.g., analysis of u_{obs} and uₛᵢₘ in combination may provide an estimate as to the error between the traces).

Though not shown in FIG. 1, one or more triggers may prompt the determination (and/or re-determination) of the value of MAX_SLOPE. As one example, the value for MAX_SLOPE may be determined at every iteration (e.g., upon determining at 170 whether to iterate again). As another example, the value for MAX_SLOPE may be determined after X number of iterations (such as after 3 iterations). As still another example, responsive to determining a change in the estimation of error between u_{obs} and uₛᵢₘ, the value for MAX_SLOPE may be changed (e.g., responsive to determining that the estimation of error has been reduced by a predetermined amount, the value for MAX_SLOPE may be reduced accordingly).

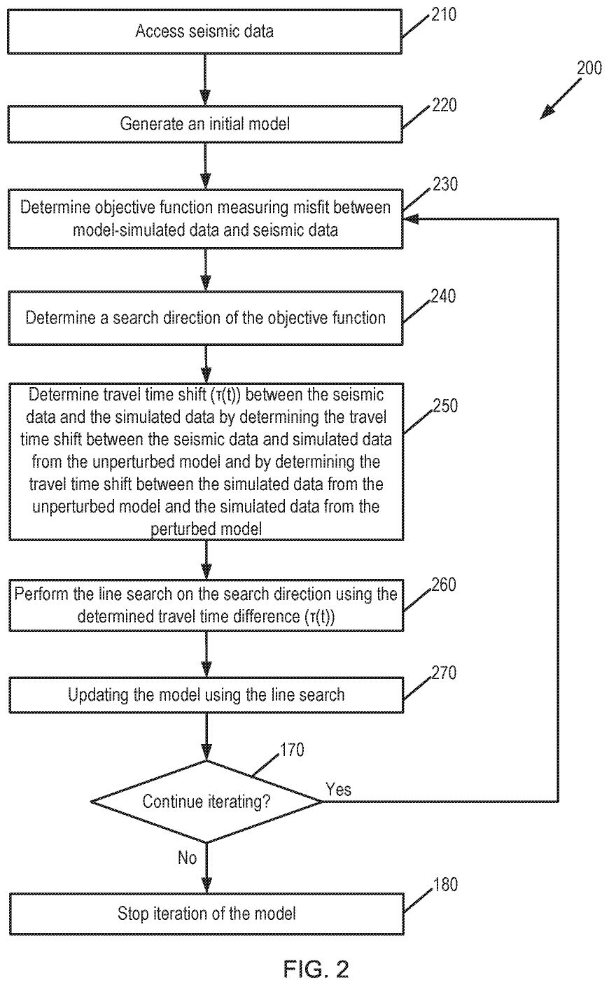

FIG. 2 is a flow diagram 200 for computing travel time shift during the model line search for FWI. At 210, seismic data is accessed. At 220, the initial model is generated (e.g., the initial model may be generated based on the accessed seismic data). At 230, the objective function measuring misfit between model-simulated data and seismic data is determined. At 240, the search direction of the objective function is determined. An example of determining the search direction is disclosed in U.S. Pat. No. 9,977,142, incorporated by reference herein in its entirety.

At 250, the travel time shift (τ(t)) between the seismic data and the simulated data is determined by determining two travel time shifts: (i) the travel time shift between the seismic data and simulated data from the unperturbed model; and (ii) the travel time shift between the simulated data from the unperturbed model and the simulated data from the perturbed model. In this regard, the travel time shift (τ(t)) between the seismic data and the simulated data may comprise a plurality of determinations of travel time shifts, such as at least two time shifts, at least three time shifts, etc. At 260, the line search on the search direction is performed using the determined travel time difference (τ(t)). An example of this is illustrated in US Patent Application Publication No. 2018/0275303 A1, incorporated by reference herein in its entirety. At 270, the model is updated based on the line search. An example of this is illustrated in U.S. Pat. No. 9,977,142, incorporated by reference herein in its entirety.

At 170, it is determined whether to continue iteration. If so, flow diagram 200 loops back to 230. If not, at 180, iteration of the model is stopped.

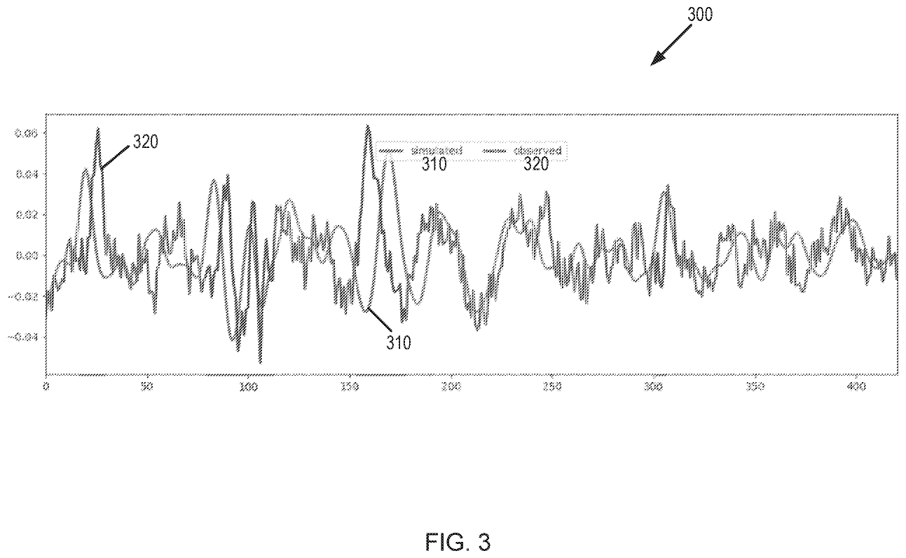

FIG. 3 is an example graph 300 of seismic input traces including observed seismic data and simulated seismic data, with the horizontal axis as time. Specifically, observed data (or an observed trace) is shown as line 320 and simulated data (or a simulated trace) is shown as line 310. As illustrated in FIG. 3, the observed data (represented as line 320) is generated by stretching the simulated data (presented as line 310) by a known sinusoidal travel time shift. Further, random white noise is added to the observed data (represented as line 320), with a signal-to-noise ratio of 2.3. The example graph 300 in FIG. 3 is merely for illustration purposes.

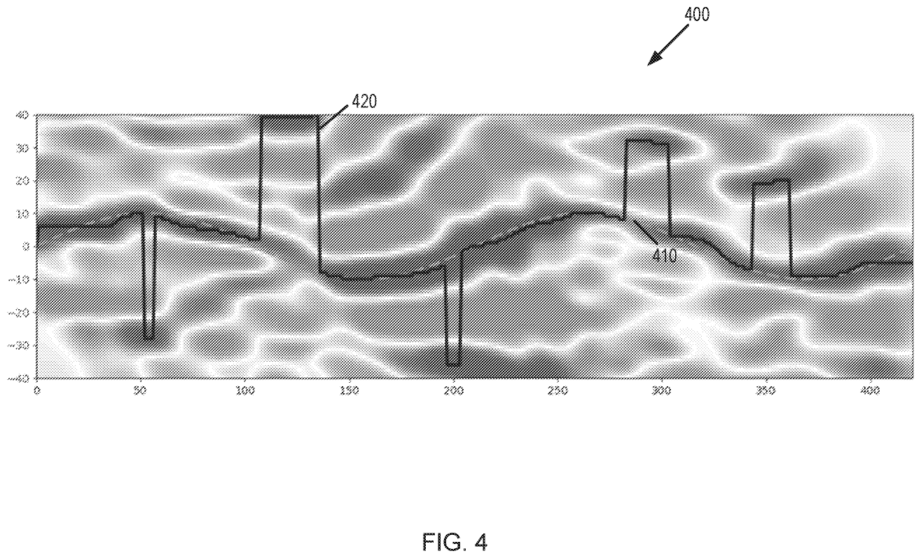

FIG. 4 is a contour plot 400 of the shifted windowed cross-correlation between simulated and observed traces, where the horizontal axis is time and the vertical axis is time shift with the solid line 420 indicating the travel time shift computed by taking the maximum of the cross-correlation function at every time slice and the dashed line 410 indicating the input time shift. As shown, the local maxima of the correlation coefficients generally follow the prescribed time shift. However, at certain locations, such as for example near the 200th time sample, the maximal correlation occurs far away from the true time shift. In turn, equation (3) results in an erroneous time shift estimation.

FIG. 5 is a contour plot 500 of the square difference between the simulated trace and the observed trace with the time shift computed according to dynamic time warping. The horizontal axis is time and the vertical axis is time shift with the solid line 520 indicating the travel time shift extracted based on equations (4) and (5), and the dashed line 510 indicating the input time shift.

As shown in FIG. 5, because the dynamic time warping algorithm seeks to minimize the difference in waveforms, the τ(t) estimation suffers many local oscillations. For example, near t≈250, the slope of the computed time shift is of the opposite sign of the prescribed one, indicating that the warping algorithm is fitting the local waveform instead of the travel time difference.

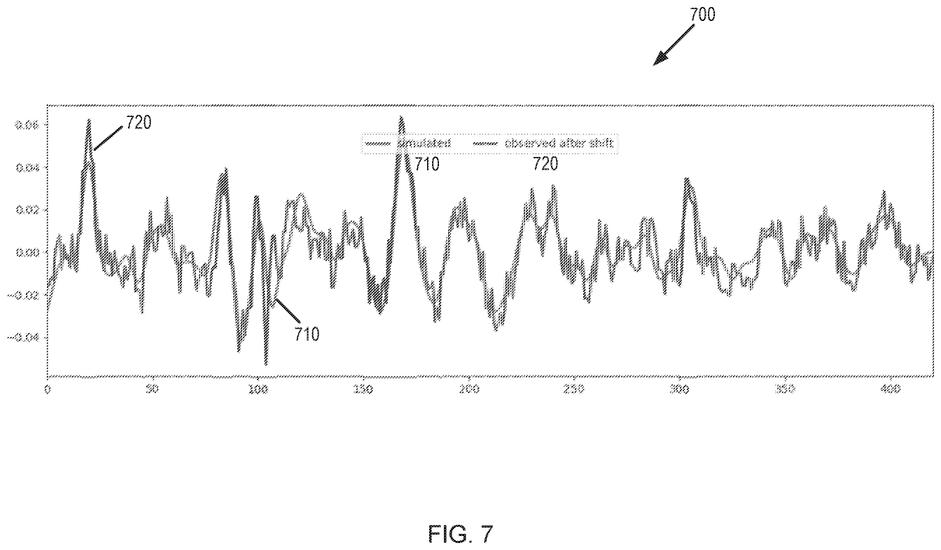

In contrast, FIGS. 6-7 are directed to an implementation of the constrained optimization methodology using equations (6) and (7). Specifically, FIG. 6 is a contour plot 600 based on the shifted windowed cross-correlation (e.g., windowed cross-correlation is multiplied by −1) between simulated and observed traces, where the horizontal axis is time and the vertical axis is time shift, with the solid line 620 indicating the travel time shift computed based on the constrained optimization algorithm, and the dashed line 610 indicating the input time shift. FIG. 7 is an example graph 700 of seismic output traces with one line 720 indicating observed data after being stretched by the time shift computed in FIG. 6, and another line 710 indicating simulated data.

In particular, FIG. 6 shows the time shift estimation, with its slope constrained, now varies smoothly in time, and is well aligned with the known time shift everywhere. In the example illustrated in FIG. 6, the parameter MAX_SLOPE is set to 0.5. As discussed above, various values between 0 and 1 may be selected for MAX_SLOPE. FIG. 7 illustrates that the two traces are well aligned after the time shift is applied to the noisy observed data.

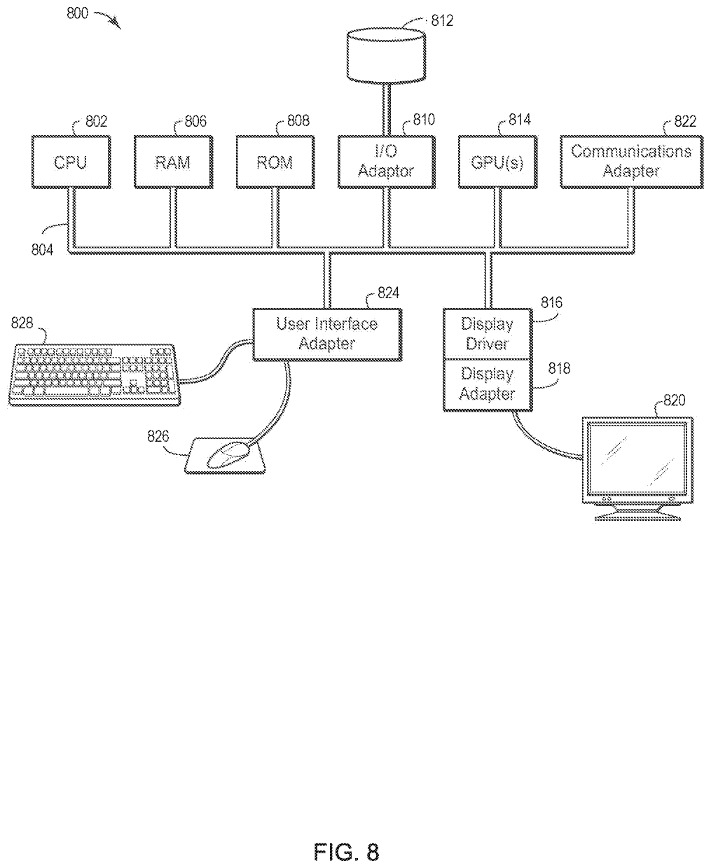

In all practical applications, the present technological advancement must be used in conjunction with a computer, programmed in accordance with the disclosures herein. For example, FIG. 8 is a diagram of an exemplary computer system 800 that may be utilized to implement the methods described herein. A central processing unit (CPU) 802 is coupled to system bus 804. The CPU 802 may be any general-purpose CPU, although other types of architectures of CPU 802 (or other components of exemplary computer system 800) may be used as long as CPU 802 (and other components of computer system 800) supports the operations as described herein. Those of ordinary skill in the art will appreciate that, while only a single CPU 802 is shown in FIG. 8, additional CPUs may be present. Moreover, the computer system 800 may comprise a networked, multi-processor computer system that may include a hybrid parallel CPU/GPU system. The CPU 802 may execute the various logical instructions according to various teachings disclosed herein. For example, the CPU 802 may execute machine-level instructions for performing processing according to the operational flow described.

The computer system 800 may also include computer components such as non-transitory, computer-readable media. Examples of computer-readable media include a random access memory (RAM) 806, which may be SRAM, DRAM, SDRAM, or the like. The computer system 800 may also include additional non-transitory, computer-readable media such as a read-only memory (ROM) 808, which may be PROM, EPROM, EEPROM, or the like. RAM 806 and ROM 808 hold user and system data and programs, as is known in the art. The computer system 800 may also include an input/output (I/O) adapter 810, a graphics processing unit (GPU) 814, a communications adapter 822, a user interface adapter 824, a display driver 816, and a display adapter 818.

The I/O adapter 810 may connect additional non-transitory, computer-readable media such as storage device(s) 812, including, for example, a hard drive, a compact disc (CD) drive, a floppy disk drive, a tape drive, and the like to computer system 800. The storage device(s) may be used when RAM 806 is insufficient for the memory requirements associated with storing data for operations of the present techniques. The data storage of the computer system 800 may be used for storing information and/or other data used or generated as disclosed herein. For example, storage device(s) 812 may be used to store configuration information or additional plug-ins in accordance with the present techniques. Further, user interface adapter 824 couples user input devices, such as a keyboard 828, a pointing device 826 and/or output devices to the computer system 800. The display adapter 818 is driven by the CPU 802 to control the display on a display device 820 to, for example, present information to the user such as subsurface images generated according to methods described herein.

The architecture of computer system 800 may be varied as desired. For example, any suitable processor-based device may be used, including without limitation personal computers, laptop computers, computer workstations, and multi-processor servers. Moreover, the present technological advancement may be implemented on application specific integrated circuits (ASICs) or very large scale integrated (VLSI) circuits. In fact, persons of ordinary skill in the art may use any number of suitable hardware structures capable of executing logical operations according to the present technological advancement. The term “processing circuit” encompasses a hardware processor (such as those found in the hardware devices noted above), ASICs, and VLSI circuits. Input data to the computer system 800 may include various plug-ins and library files. Input data may additionally include configuration information.

Preferably, the computer is a high performance computer (HPC), known to those skilled in the art. Such high performance computers typically involve clusters of nodes, each node having multiple CPU's and computer memory that allow parallel computation. The models may be visualized and edited using any interactive visualization programs and associated hardware, such as monitors and projectors. The architecture of system may vary and may be composed of any number of suitable hardware structures capable of executing logical operations and displaying the output according to the present technological advancement. Those of ordinary skill in the art are aware of suitable supercomputers available from Cray or IBM or other cloud computing based vendors such as Microsoft, Amazon.

It is intended that the foregoing detailed description be understood as an illustration of selected forms that the invention can take and not as a definition of the invention. It is only the following claims, including all equivalents that are intended to define the scope of the claimed invention. Further, it should be noted that any aspect of any of the preferred embodiments described herein may be used alone or in combination with one another. Finally, persons skilled in the art will readily recognize that in preferred implementation, some or all of the steps in the disclosed method are performed using a computer so that the methodology is computer implemented. In such cases, the resulting physical properties model may be downloaded or saved to computer storage.

The following example embodiments of the invention are also disclosed.

Embodiment 1: A method of estimating travel time difference between two seismic traces, the method comprising: accessing seismic data, the seismic data being generated from one or more sensors; determining, based on the seismic data, an observed trace; computing, using at least one computer and based on a model of the seismic data, a simulated trace; computing, using the at least one computer, a windowed cross correlation between the observed trace and the simulated trace; determining travel time difference between the observed trace and the simulated trace by maximizing the windowed cross correlation at least partly while constraining at least one aspect of the travel time difference between the observed trace and the simulated trace; and using the determined travel time difference between the observed trace and the simulated trace in order to update the model of the seismic data.

Embodiment 2: The method of embodiment 1, wherein the at least one aspect of the travel time difference constrained while maximizing cross correlation comprises a derivative of the travel time difference relative to time.

Embodiment 3: The method of any of embodiments 1 and 2, wherein the derivative of the travel time difference relative to time is constrained while maximizing cross correlation to be less than a derivative value.

Embodiment 4: The method of any of embodiments 1-3, wherein an absolute value of the derivative value is no greater than 1 and no less than 0.

Embodiment 5: The method of any of embodiments 1-4, wherein maximizing the windowed cross correlation is over a period of time.

Embodiment 6: The method of any of embodiments 1-5, wherein the travel time difference τ(t) is calculated by integrating over the period of time for:

$$τ ( t ) = {arg min}_{ξ ( t )} \int - C ( t ; ξ ( t ) ) dt$$

under a constraint of:

|dτ(t)/dt|≤MAX_SLOPE,

wherein MAX_SLOPE is a constant that is between 0 and 1.

Embodiment 7: The method of any of embodiments 1-6, further comprising dynamically selecting the derivative value.

Embodiment 8: The method of any of embodiments 1-7, further comprising estimating error in travel time of the simulated trace; and wherein the derivative value is dynamically selected based on the estimated error in travel time of the simulated trace.

Embodiment 9: The method of any of embodiments 1-8, wherein the model is updated in multiple iterations such that the model in one iteration is m^{(x)} and the model in a subsequent iteration is m^{(y)}; wherein the derivative value for the one iteration is dynamically selected based on estimating the error in the travel time of the simulated trace using model m^{(x)} ; and wherein the derivative value for the subsequent iteration is dynamically selected based on estimating the error in the travel time of the simulated trace using model m^{(y)}.

Embodiment 10: The method of any of embodiments 1-9, wherein the derivative value for the subsequent iteration is selected to be less than the derivative value for the one iteration.

Embodiment 11: The method of any of embodiments 1-10, wherein the model is updated in multiple iterations; and wherein the derivative value is constant for the multiple iterations.

Embodiment 12: The method of any of embodiments 1-11, further comprising estimating error in travel time of the simulated trace for a first iteration; and wherein the derivative value is dynamically selected based on the estimated error in travel time of the simulated trace for the first iteration.

Embodiment 13: An iterative method for inverting measured geophysical data to infer a subsurface model of one or more physical properties, the method comprising: (a) using a subsurface property model, computing, using at least one computer, an objective function measuring misfit between model-simulated data and the measured geophysical data, wherein the model-simulated data are generated using a computer; (b) computing, using the at least one computer, a search direction of the objective function with respect to parameters of the subsurface property model; (c) computing, using at least one computer, a travel time shift between simulated data from the subsurface property model perturbed and observed data by computing a plurality of travel time shifts, at least one of the plurality of travel time shifts computed being independent of the observed data, the observed data based on the geophysical data; (d) using the computed travel time shift for performing a line search; (e) updating the subsurface property model using the line search; and (f) repeating (a)-(e) at least once using the updated subsurface property model.

Embodiment 14: The method of embodiment 13, wherein at least another of the plurality of travel time shifts is independent of simulated data from the subsurface property model perturbed.

Embodiment 15: The method of any of embodiments 13 and 14, wherein computing the travel time shift comprises computing a first travel time shift between simulated data from the subsurface property model unperturbed and the observed data and computing at least a second time shift; and wherein the second time shift is independent of the observed data.

Embodiment 16: The method of any of embodiments 13-15, wherein the second time shift comprises a time shift between the simulated data from the subsurface property model unperturbed and the simulated data from the subsurface property model perturbed.

Embodiment 17: The method of any of embodiments 13-16, wherein the subsurface property model unperturbed comprises m⁽⁰⁾; wherein the subsurface property model perturbed comprises a series of perturbed subsurface property models m^{(j)}=m⁽⁰⁾+α^{(j)}·s (j=1, 2, . . . , J), where s is a normalized model search direction and α^{(j)} is search step length; and wherein e of the series of perturbed subsurface property models m^{(j)} results in simulated data u^{(j)}.

Embodiment 18: The method of any of embodiments 13-17, wherein the plurality of travel time shifts consist of a first travel time shift independent of simulated data from the subsurface property model perturbed and a second travel time shift independent of the observed data.

Embodiment 19: The method of any of embodiments 13-18, wherein the first travel time shift and the second travel time shift are both computed as a shift from a reference trace.

Embodiment 20: The method of any of embodiments 1-19, wherein the reference trace is data simulated based on the subsurface property model unperturbed.

### REFERENCES

The following references are hereby incorporated by reference herein in their entirety:

U.S. Pat. No. 9,977,142.

US Patent Application Publication No. 2018/0275303 A1.

Y. Luo and G. T. Schuster, “Wave-equation traveltime inversion,” GEOPHYSICS, vol. 56, no. 5, pp. 645-653, 1991.

D. Hale, “A method for estimating apparent displacement vectors from time-lapse seismic images,” GEOPHYSICS, vol. 74, no. 5, pp. 99-107, 2009.

S. A. Hall, “A methodology for 7D warping and deformation monitoring,” GEOPHYSICS, vol. 71, no. 4, pp. 21-31, 2006.

D. Cho, “Cross-correlation based time warping of one-dimensional seismic signals,” CREWES Research Report, Volume 25, 2013.

N.-P. V. Nielsen, J. M. Carstensen and J. Smedsgaard, “Aligning of single and multiple wavelength chromatographic profiles for chemometric data analysis using correlation optimised warping,” Journal of Chromatography A, vol. 805, pp. 17-35, 1998.

Giorgio Tomasi, F. v. d. Berg and C. Andersson, “Correlation optimized warping and dynamic time warping as preprocessing methods for chromatographic data,” Journal of Chemometrics, vol. 18, pp. 231-241, 2004.

D. Hale, “Dynamic warping of seismic images,” GEOPHYSICS, vol. 78, no. 2, pp. 105-115, 2013.

H. Sakoe and S. Chiba, “Dynamic Programming Algorithm Optimization for Spoken Word Recognition,” IEEE Transactions on Acoustics, Speech, and Signal Processing, vol. 26, no. 1, pp. 43-49, 1978.

1. A method of estimating travel time difference between two seismic traces, the method comprising:
accessing seismic data, the seismic data being generated from one or more sensors;
determining, based on the seismic data, an observed trace;
computing, using at least one computer and based on a model of the seismic data, a simulated trace;
computing, using the at least one computer, a windowed cross correlation between the observed trace and the simulated trace;
determining travel time difference between the observed trace and the simulated trace by maximizing the windowed cross correlation at least partly while constraining at least one aspect of the travel time difference between the observed trace and the simulated trace; and
using the determined travel time difference between the observed trace and the simulated trace in order to update the model of the seismic data.

2. The method of claim 1, wherein the at least one aspect of the travel time difference constrained while maximizing cross correlation comprises a derivative of the travel time difference relative to time.

3. The method of claim 2, wherein the derivative of the travel time difference relative to time is constrained while maximizing cross correlation to be less than a derivative value.

4. The method of claim 3, wherein an absolute value of the derivative value is no greater than 1 and no less than 0.

5. The method of claim 4, wherein maximizing the windowed cross correlation is over a period of time.

6. The method of claim 5, wherein the travel time difference τ(t) is calculated by integrating over the period of time for:
$$τ ( t ) = {arg min}_{ξ ( t )} \int - C ( t ; ξ ( t ) ) dt$$
under a constraint of:

|dτ(t)/dt|≤MAX_SLOPE,
wherein MAX_SLOPE is a constant that is between 0 and 1.

7. The method of claim 3, further comprising dynamically selecting the derivative value.

8. The method of claim 7, further comprising estimating error in travel time of the simulated trace; and
wherein the derivative value is dynamically selected based on the estimated error in travel time of the simulated trace.

9. The method of claim 8, wherein the model is updated in multiple iterations such that the model in one iteration is m^{(x)} and the model in a subsequent iteration is m^{(y)};
wherein the derivative value for the one iteration is dynamically selected based on estimating the error in the travel time of the simulated trace using model m^{(x)}; and
wherein the derivative value for the subsequent iteration is dynamically selected based on estimating the error in the travel time of the simulated trace using model m^{(y)}.

10. The method of claim 9, wherein the derivative value for the subsequent iteration is selected to be less than the derivative value for the one iteration.

11. The method of claim 3, wherein the model is updated in multiple iterations; and
wherein the derivative value is constant for the multiple iterations.

12. The method of claim 11, further comprising estimating error in travel time of the simulated trace for a first iteration; and
wherein the derivative value is dynamically selected based on the estimated error in travel time of the simulated trace for the first iteration.

13. An iterative method for inverting measured geophysical data to infer a subsurface model of one or more physical properties, the method comprising:
(a) using a subsurface property model, computing, using at least one computer, an objective function measuring misfit between model-simulated data and the measured geophysical data, wherein the model-simulated data are generated using a computer;
(b) computing, using the at least one computer, a search direction of the objective function with respect to parameters of the subsurface property model;
(c) computing, using at least one computer, a travel time shift between simulated data from the subsurface property model perturbed and observed data by computing a plurality of travel time shifts, at least one of the plurality of travel time shifts computed being independent of the observed data, the observed data based on the geophysical data;
(d) using the computed travel time shift for performing a line search;
(e) updating the subsurface property model using the line search; and
(f) repeating (a)-(e) at least once using the updated subsurface property model.

14. The method of claim 13, wherein at least another of the plurality of travel time shifts is independent of simulated data from the subsurface property model perturbed.

15. The method of claim 14, wherein computing the travel time shift comprises computing a first travel time shift between simulated data from the subsurface property model unperturbed and the observed data and computing at least a second time shift; and
wherein the second time shift is independent of the observed data.

16. The method of claim 15, wherein the second time shift comprises a time shift between the simulated data from the subsurface property model unperturbed and the simulated data from the subsurface property model perturbed.

17. The method of claim 16, wherein the subsurface property model unperturbed comprises m⁽⁰⁾;
wherein the subsurface property model perturbed comprises a series of perturbed subsurface property models m^{(j)}=m⁽⁰⁾+α^{(j)}·s (j=1, 2, . . . , J), where s is a normalized model search direction and GO is search step length; and
wherein e of the series of perturbed subsurface property models m^{(j)} results in simulated data u^{(j)}.

18. The method of claim 13, wherein the plurality of travel time shifts consist of a first travel time shift independent of simulated data from the subsurface property model perturbed and a second travel time shift independent of the observed data.

19. The method of claim 18, wherein the first travel time shift and the second travel time shift are both computed as a shift from a reference trace.

20. The method of claim 19, wherein the reference trace is data simulated based on the subsurface property model unperturbed.
